(19) United States
(12) Patent Application Publication
(10) Pub. No.: US 2024/0014327 A1
(43) Pub. Date: Jan. 11, 2024

(54) POWER CONVERSION APPARATUS AND BIDIRECTIONAL SWITCH

(71) Applicant: FUJI ELECTRIC CO., LTD., Kanagawa (JP)

(72) Inventor: Manabu TAKEI, Shiojiri-city (JP)

(21) Appl. No.: 18/472,223

(22) Filed: Sep. 22, 2023

Related U.S. Application Data
(63) Continuation of application No. PCT/JP2022/031559, filed on Aug. 22, 2022.

(30) Foreign Application Priority Data
Oct. 14, 2021 (JP) 2021-168774

(51) Int. Cl. H01L 29/868; H02M 1/08; H03K 17/74; H03K 17/687; H01L 29/06

(52) U.S. Cl. CPC H01L 29/868; H02M 1/08; H03K 17/74; H03K 17/687; H01L 29/0615

(57) ABSTRACT

A bidirectional switch, having: a first silicon carbide transistor; a first diode which is provided in series with the first silicon carbide transistor, and of which on voltage is lower than that of a built-in diode of the first silicon carbide transistor at a rated current of the bidirectional switch; a second silicon carbide transistor provided in parallel with the first diode; a second diode which is provided in series with the second silicon carbide transistor and in parallel with the first silicon carbide transistor, and of which on voltage is lower than that of a built-in diode of the second silicon carbide transistor at the rated current of the bidirectional switch; and a connection line which connects a first connection point between the first silicon carbide transistor and the first diode, and a second connection point between the second silicon carbide transistor and the second diode, is provided.

The contents of the following patent application(s) are incorporated herein by reference:
NO. 2021-168774 filed in JP on Oct. 14, 2021
NO. PCT/JP2022/031559 filed in WO on Aug. 22, 2022

### BACKGROUND

### 1. Technical Field

The present invention relates to a power conversion apparatus and a bidirectional switch.

### 2. Related Art

Conventionally known is a power converter using a bidirectional switch (for example, refer to Patent Documents 1 and 2).

### PRIOR ART DOCUMENT

### Patent Document

Patent Document 1: Japanese Patent No. 4839943
Patent Document 2: Japanese Patent No. 5999526

### BRIEF DESCRIPTION OF THE DRAWINGS

FIG. 1 is a diagram showing one example of a power conversion apparatus 200 according to one embodiment of the present invention.

FIG. 2 is a diagram showing one example of a bidirectional switch 100.

FIG. 3 is a diagram showing an example of operations of the bidirectional switch 100.

FIG. 4 is a diagram showing an example of operations of the bidirectional switch 100.

FIG. 5 is a diagram showing a first bidirectional switch 100-a and a second bidirectional switch 100-b which are connected to common output phase.

FIG. 6 is a diagram showing examples of waveforms of gate voltages Qa1, Qa2, Qb1, and Qb2.

FIG. 7 illustrates a state at time t0 of FIG. 6.

FIG. 8 illustrates a state at time t1 of FIG. 6.

FIG. 9 illustrates a state at time t2 of FIG. 6.

FIG. 10 illustrates a state at time t3 of FIG. 6.

FIG. 11 illustrates a state at time t4 of FIG. 6.

FIG. 12 is a diagram showing another example of operations of the bidirectional switch 100 in an on state.

FIG. 13 is a diagram showing another example of architecture of the bidirectional switch 100.

FIG. 14 is a diagram showing one example of structure of a first diode 121.

FIG. 15 illustrates one example of carrier concentration distribution taken along a line A-A of FIG. 14.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention. Note that in the present specification and the diagrams, elements having substantially the same function and architecture are denoted with a same reference sign to omit duplicated descriptions, and illustrations of elements that are not directly related to the present invention will be omitted. Further, in one diagram, elements having the same functions and architecture are denoted by a representative reference sign, and other reference signs for the elements may be omitted. In the present specification, a case where a term such as “same” or “equal” is mentioned may include a case having an error due to a variation in manufacturing or the like. This error is, for example, within 10%. A magnitude of current or the like described in the present specification is, unless particularly defined, a magnitude at a room temperature, i.e., 25 degrees Celsius.

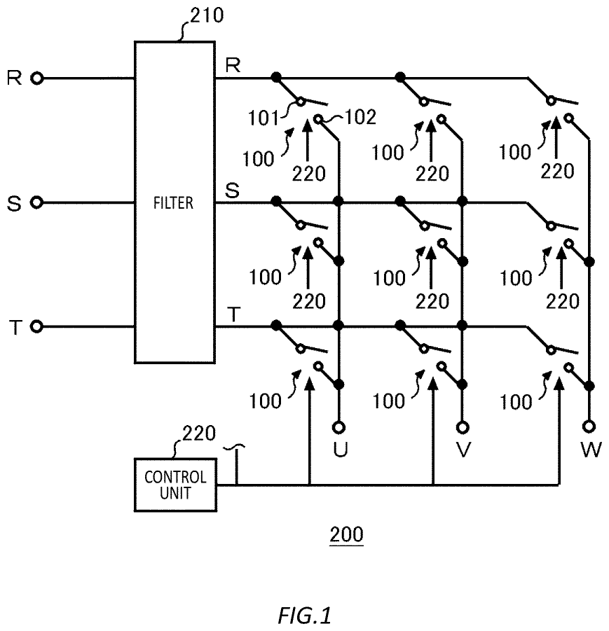

FIG. 1 is a diagram showing one example of a power conversion apparatus 200 according to one embodiment of the present invention. The power conversion apparatus 200 generates output power from input power by switching one or more bidirectional switches 100. The power conversion apparatus 200 may be input with power of multiple phases, and may output power of multiple phases. The power conversion apparatus 200 of the present example is input with power of three phases (R, S, T) and outputs power of three phases (U, V, W). The power conversion apparatus 200 of the present example is a matrix converter having multiple bidirectional switches 100 that switch which wires of output phases (U, V, W) are connected to wires of input phases (R, S, T), respectively. However, a power conversion apparatus 200 is not limited to a matrix converter.

The power conversion apparatus 200 includes the one or more bidirectional switches 100 and a control unit 220. The power conversion apparatus 200 may include a filter 210. The control unit 220 controls an on state and an off state of each of the bidirectional switches 100. The filter 210 removes predetermined frequency components of voltage or current to be input, or voltage or current to be output. The filter 210 may be, for example, a low-pass filter that smooths voltage or current.

The each of the bidirectional switches 100 switches whether to pass power input into a first terminal 101 through a second terminal 102. The bidirectional switch 100 of the present example is provided for every combination of an input phase and an output phase. For example, for a power conversion apparatus 200 with three-phase input/three-phase output, there are 3×3=9 combinations of input phases and output phases. In this case, the power conversion apparatus 200 may have nine bidirectional switches 100.

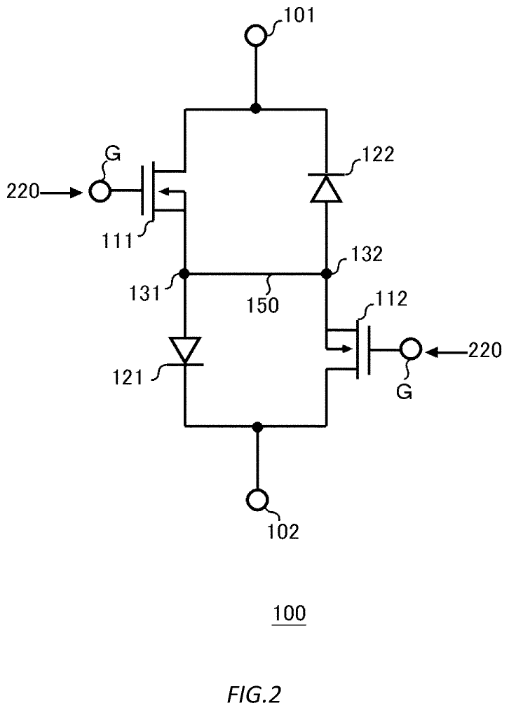

FIG. 2 is a diagram showing one example of the bidirectional switch 100. Even though FIG. 2 shows a single bidirectional switch 100, the each of the bidirectional switches 100 can have the structure shown in FIG. 2. The bidirectional switch 100 has the first terminal 101, the second terminal 102, a first silicon carbide transistor 111, a first diode 121, a second silicon carbide transistor 112, a second diode 122, and a connection line 150. The first terminal 101 and the second terminal 102 correspond to the first terminal 101 and the second terminal 102 shown in FIG. 1, respectively.

A silicon carbide transistor is a transistor formed on a silicon carbide (SiC) substrate. The silicon carbide transistors of the present example are MOSFETs formed on SiC substrates.

The first silicon carbide transistor 111 is provided between the first terminal 101 and the second terminal 102. The first silicon carbide transistor 111 transitions between an on state and an off state, depending on a control signal input from the control unit 220 to a control terminal G. The first silicon carbide transistor 111 of the present example is an N channel MOSFET of which a drain terminal is connected to the first terminal 101.

Note that, if arrangements of circuit elements are described in the present specification, the description is about arrangements on electrical paths. For example, by the phrase “the first silicon carbide transistor 111 is provided between the first terminal 101 and the second terminal 102”, it is meant that the first silicon carbide transistor 111 is provided on an electrical path connecting the first terminal 101 and the second terminal 102. In this case, a position of the first silicon carbide transistor 111 in the space may not be between the first terminal 101 and the second terminal 102.

The first diode 121 is provided in series with the first silicon carbide transistor 111, between the first terminal 101 and the second terminal 102. The first diode 121 is arranged such that its forward direction is a direction directed from the first terminal 101 toward the second terminal 102. The first silicon carbide transistor 111 and the first diode 121 are connected at a first connection point 131. In the present example, the first silicon carbide transistor 111 is provided between the first terminal 101 and the first connection point 131, and the first diode 121 is provided between the first connection point 131 and the second terminal 102. In another example, the first silicon carbide transistor 111 and the first diode 121 can switch their positions of arrangement.

The second silicon carbide transistor 112 is provided in parallel with the first diode 121 between the first terminal 101 and the second terminal 102. If the first diode 121 is connected to the second terminal 102, like that shown in FIG. 2, the second silicon carbide transistor 112 is connected to the second terminal 102, in parallel with the first diode 121. Alternatively, if the first diode 121 is connected to the first terminal 101, the second silicon carbide transistor 112 is connected to the first terminal 101, in parallel with the first diode 121. The second silicon carbide transistor 112 transitions between an on state and an off state, depending on a control signal input from the control unit 220 to a control terminal G. The second silicon carbide transistor 112 of the present example is an N channel MOSFET of which a drain terminal is connected to the second terminal 102.

The second diode 122 is provided in series with the second silicon carbide transistor 112, between the first terminal 101 and the second terminal 102. Also, the second diode 122 is provided in parallel with the first silicon carbide transistor 111. The second diode 122 is arranged such that its forward direction is a direction directed from the second terminal 102 toward the first terminal 101. The second silicon carbide transistor 112 and the second diode 122 are connected at a second connection point 132. In the present example, the second diode 122 is provided between the first terminal 101 and the second connection point 132, and the second silicon carbide transistor 112 is provided between the second connection point 132 and the second terminal 102. In another example, the second silicon carbide transistor 112 and the second diode 122 can switch their positions of arrangement.

The connection line 150 is a wire that connects the first connection point 131 and the second connection point 132. If both of the first silicon carbide transistor 111 and the second silicon carbide transistor 112 are off, regardless of magnitudes of voltages of the first terminal 101 and the second terminal 102, no current flows between the first terminal 101 and the second terminal 102, and the bidirectional switch 100 is turned off.

In a case of turning on the bidirectional switch 100, the control unit 220 turns on the first silicon carbide transistor 111 and the second silicon carbide transistor 112 simultaneously or one after another. Thereby, regardless of magnitudes of voltages of the first terminal 101 and the second terminal 102, current flows between the first terminal 101 and the second terminal 102, and the bidirectional switch 100 is turned on.

For example, if the first silicon carbide transistor 111 is turned on when a voltage of the first terminal 101 is higher than a voltage of the second terminal 102, current flows between the first terminal 101 and the second terminal 102 through the first silicon carbide transistor 111 and the first diode 121 which are in forward conducting states. In this case, the second silicon carbide transistor 112 can also be controlled to be on. In this way, current is split into the first diode 121 and the second silicon carbide transistor 112 that is in a reverse conducting state, and thereby an overall on resistance of the bidirectional switch 100 can be reduced. Note that, a forward conducting state of a transistor refers to a state in which current flows from a drain terminal to a source terminal, and a reverse conducting state refers to a state in which current flows from a source terminal to a drain terminal.

If the second silicon carbide transistor 112 is turned on when a voltage of the second terminal 102 is higher than a voltage of the first terminal 101, current flows between the second terminal 102 and the first terminal 101 through the second silicon carbide transistor 112 and the second diode 122 which are in forward conducting states. In this case, the first silicon carbide transistor 111 can also be controlled to be on. In this way, current is split into the second diode 122 and the first silicon carbide transistor 111 that is in a reverse conducting state, and thereby an overall on resistance of the bidirectional switch 100 can be reduced.

By using the silicon carbide transistors as switching devices of the bidirectional switch 100, losses in switching devices can be reduced. Additionally, even if a gate of the silicon carbide transistor is off, a built-in diode of the silicon carbide transistor may be turned on in response to a reverse voltage. In other words, the silicon carbide transistor has no reverse-blocking capability. Meanwhile, by providing each silicon carbide transistor with a diode connected in reverse series, current can be cut off against a forward voltage and a reverse voltage.

On voltage of the first diode 121 is lower than that of the built-in diode of the first silicon carbide transistor 111 at a rated current of the bidirectional switch 100. On voltage of each diode is a forward voltage of the each diode. The rated current of the bidirectional switch 100 is rating of current that flows between the first terminal 101 and the second terminal 102. For a value of the rated current, a specification value defined by a manufacturer, a user, or the like of the bidirectional switch 100 may be used. For the specification value for the rated current, a value of current density per unit area (A/cm²) of a transistor chip or diode chip may be specified. In this case, the rated value of the current that flows between the first terminal 101 and the second terminal 102 may be set by multiplying an area of the transistor chip or diode chip by the current density. For when predetermined rated currents are caused to flow into the first silicon carbide transistor 111 and the first diode 121, on voltage of the first silicon carbide transistor 111 may be compared to on voltage of the first diode 121. Here, for the on voltage of each of the first silicon carbide transistor 111 and the first diode 121, a value measured at a room temperature, i.e., 25 degrees Celsius, may be used. By lowering the on voltage of the first diode 121, losses in the first diode 121 can be reduced. At the rated current, the on voltage of the first diode 121 may be lower than on voltage of the built-in diode of the second silicon carbide transistor 112. At the rated current, the on voltage of the first diode 121 may be equal to or less than 0.9 times, 0.7 times, or 0.5 times the on voltage of the built-in diode of the first silicon carbide transistor 111. The on voltage of the diode can be adjusted depending on: whether there is a factor affecting lifetime (i.e., a recombination center of crystal defects etc.) in a semiconductor substrate; an impurity concentration in the semiconductor substrate; and the like.

On voltage of the second diode 122 is lower than that of the built-in diode of the second silicon carbide transistor 112 at the rated current of the bidirectional switch 100. By lowering the on voltage of the second diode 122, losses in the second diode 122 can be reduced. At the rated current, the on voltage of the second diode 122 may be lower than the on voltage of the built-in diode of the first silicon carbide transistor 111. At the rated current, the on voltage of the second diode 122 may be equal to or less than 0.9 times, 0.7 times, or 0.5 times the on voltage of the built-in diode of the second silicon carbide transistor 112.

A breakdown voltage of the first diode 121 may be higher than a breakdown voltage of the first silicon carbide transistor 111. The breakdown voltage of the diode may be a value of a reverse voltage at which reverse current starts flowing. The breakdown voltage of the transistor may be a value of a forward voltage at which current starts flowing when the gate of the transistor is off. By designing such that the breakdown voltage of the first diode 121 is higher than the breakdown voltage of the first silicon carbide transistor 111, in the series circuit having the first diode 121 and the first silicon carbide transistor 111, avalanche withstand capability is decided at the first silicon carbide transistor 111. Therefore, because there is no need of taking into account avalanche withstand capability for the first diode 121, it is easy to lower the above-described on voltage, i.e., forward voltage, of the first diode 121. The breakdown voltage of the diode can be adjusted depending on a thickness of the semiconductor substrate to be used, an impurity concentration in the semiconductor substrate, and the like.

A breakdown voltage of the second diode 122 may be higher than a breakdown voltage of the second silicon carbide transistor 112. By designing such that the breakdown voltage of the second diode 122 is higher than the breakdown voltage of the second silicon carbide transistor 112, in the series circuit having the second diode 122 and the second silicon carbide transistor 112, avalanche withstand capability is decided at the second silicon carbide transistor 112. Therefore, because there is no need of taking into account avalanche withstand capability for the second diode 122, it is easy to lower the above-described on voltage, i.e., forward voltage, of the second diode 122.

The first diode 121 and the second diode 122 of the present example are silicon diodes having P-N junctions. Thus, the each diode can be manufactured at low cost. The first diode 121 and the second diode 122 may be provided on separate chips. The first silicon carbide transistor 111 and the second silicon carbide transistor 112 may be provided on separate chips, or on the same chip.

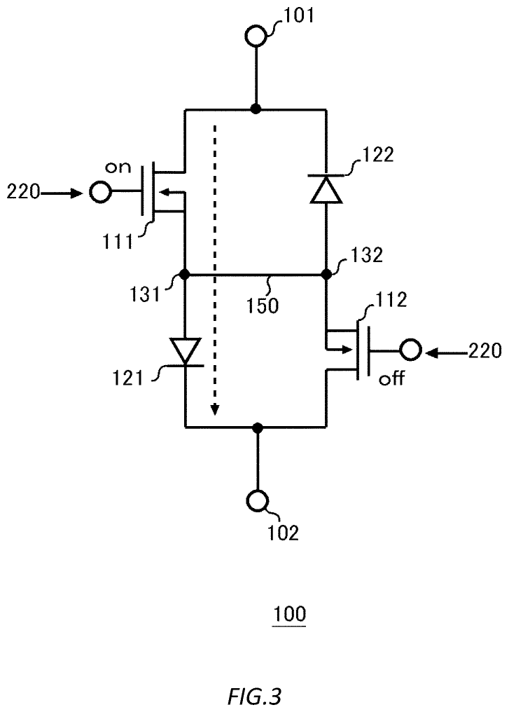

FIG. 3 is a diagram showing an example of operations of the bidirectional switch 100. In each diagram, each transistor that is on may be shown with the term “on”, and each transistor that is off may be shown with the term “off”. The present example shows the bidirectional switch 100 during its transition from on to off. In the power conversion apparatus 200 shown in FIG. 1, while one of two bidirectional switches 100 connected to common output phase is controlled to be off from on, the another bidirectional switch is controlled to be on from off. At this time, it is preferable that, instead of simultaneously turning on or off two transistors of the bidirectional switch 100, the two transistors are controlled one after another.

When causing the bidirectional switch 100 to transition from off to on, firstly, the first silicon carbide transistor 111 is caused to transition from off to on. Here, the second silicon carbide transistor 112 is off.

In the state shown in FIG. 3, current that passed through the first silicon carbide transistor 111 may flow into the first diode 121 and the built-in diode of the second silicon carbide transistor 112. In each diagram, a current path may be schematically shown by a dotted line arrow. If forward current flows into the built-in diode of the second silicon carbide transistor 112 being off, a stacking fault (SF) may expand from a basal plane dislocation (BPD) in a SiC crystal of the semiconductor substrate, and thereby the on voltage of the second silicon carbide transistor 112 may increase.

A start-up voltage of the first diode 121 may be lower than a start-up voltage of the built-in diode of the second silicon carbide transistor 112. A start-up voltage of the each diode is a forward voltage at which forward current starts flowing into the each diode. In this way, in the state shown in FIG. 3, current flows into the first diode 121 before current flows into the built-in diode of the second silicon carbide transistor 112. Thereby, expansion of the stacking fault in the second silicon carbide transistor 112 can be prevented. The start-up voltage of the first diode 121 may be lower than the start-up voltage of the built-in diode of the second silicon carbide transistor 112 by equal to or more than 0.2 V, 0.5 V, 1 V, or 2 V. Similarly, a start-up voltage of the second diode 122 may be lower than a start-up voltage of the built-in diode of the first silicon carbide transistor 111.

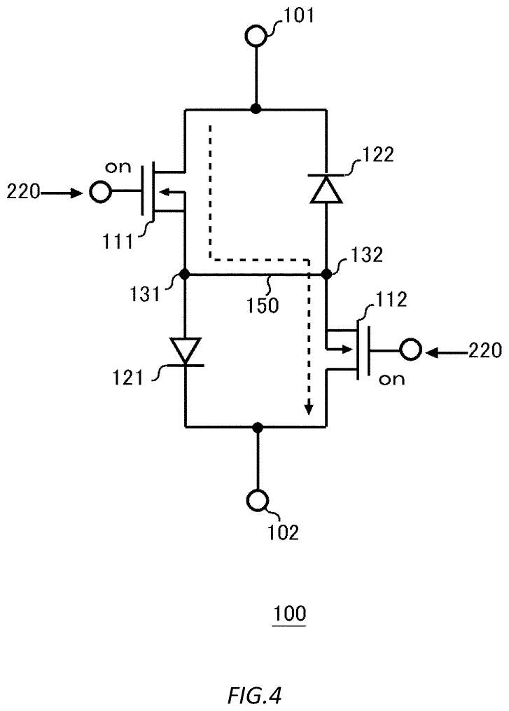

FIG. 4 is a diagram showing an example of operations of the bidirectional switch 100. The present example shows the bidirectional switch 100 being on. In the present example, both of the first silicon carbide transistor 111 and the second silicon carbide transistor 112 are on. In this case, as shown in FIG. 4, current flows through the first silicon carbide transistor 111, connection line 150, and second silicon carbide transistor 112.

As described above, current from the first silicon carbide transistor 111 may be split into the first diode 121 too. The current that flows in the first diode 121 may be smaller than the current that flows in the second silicon carbide transistor 112. The current that flows in the first diode 121 may be equal to or less than 10%, or 1% of the current that flows in the second silicon carbide transistor 112. Otherwise, no current may flow in the first diode 121.

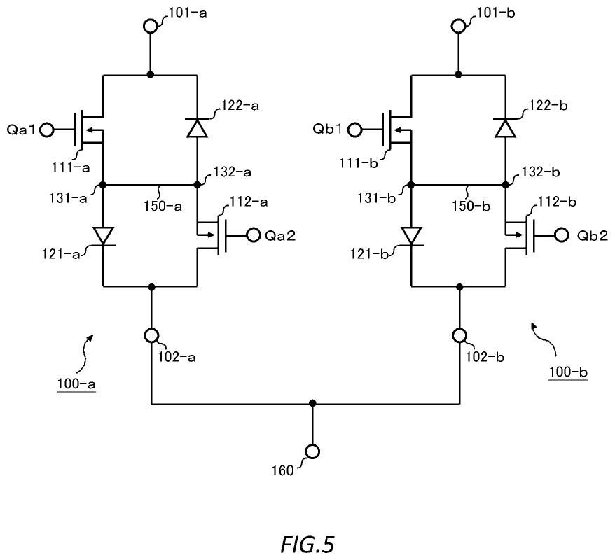

FIG. 5 is a diagram showing a first bidirectional switch 100-a and a second bidirectional switch 100-b which are connected to common output phase. The first bidirectional switch 100-a and the second bidirectional switch 100-b have architecture the same as the architecture of the bidirectional switch 100 shown in FIG. 2. A reference sign for each component of the first bidirectional switch 100-a is denoted with a branch number “-a”, and a reference sign of each component of the second bidirectional switch 100-b is denoted with a branch number “-b”. A second terminal 102-a of the first bidirectional switch 100-a and a second terminal 102-b of the second bidirectional switch 100-b are connected to a terminal 160. The terminal 160 is connected to any output phase.

Qa1 is a gate voltage applied to a first silicon carbide transistor 111-a, and Qa2 is a gate voltage applied to a second silicon carbide transistor 112-a of the first bidirectional switch 100-a. Similarly, Qb1 is a gate voltage applied to a first silicon carbide transistor 111-b, and Qb2 is a gate voltage applied to a second silicon carbide transistor 112-b of the second bidirectional switch 100-b. Each of the gate voltages may be generated by the control unit 220.

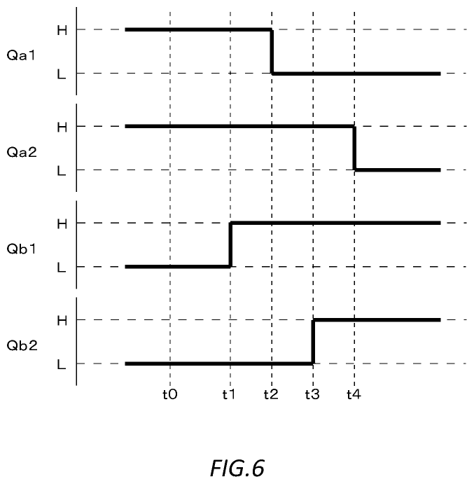

FIG. 6 is a diagram showing examples of waveforms of the gate voltages Qa1, Qa2, Qb1, and Qb2. The control unit 220 of the present example causes the first bidirectional switch 100-a to transition from on to off, and the bidirectional switch 100-b to transition from off to on. In other words, the control unit 220 causes a transition to take place from a state in which current is flowing between the first bidirectional switch 100-a and the terminal 160 to a state in which current is flowing between the second bidirectional switch 100-b and the terminal 160. Such control is referred to as commutating current from the first bidirectional switch 100-a to the second bidirectional switch 100-b.

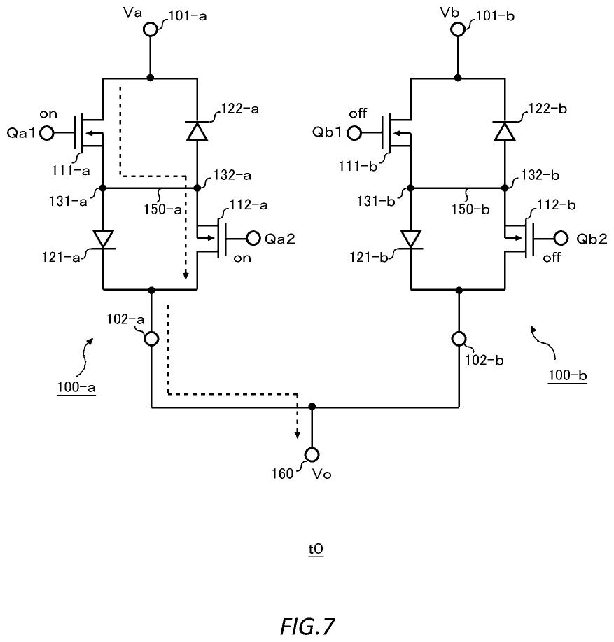

FIG. 7 illustrates a state at time t0 of FIG. 6. Note that, in FIG. 7 and subsequent diagrams, a voltage Va of a first terminal 101-a is assumed to be larger than a voltage Vb of a first terminal 101-b. At time t0, the gate voltages Qa1 and Qa2 are at H levels, and the gate voltages Qb1 and Qb2 are at L levels. Each silicon carbide transistor is turned on when a gate voltage of H level is applied, and turned off when a gate voltage of L level is applied.

In the present example, both of the first silicon carbide transistor 111-a and the second silicon carbide transistor 112-a are on. Thereby, the first bidirectional switch 100-a is on. Here, the first silicon carbide transistor 111-b and the second silicon carbide transistor 112-b are off. Thereby, the second bidirectional switch 100-b is off. Therefore, current flows from the first terminal 101-a of the first bidirectional switch 100-a to the terminal 160.

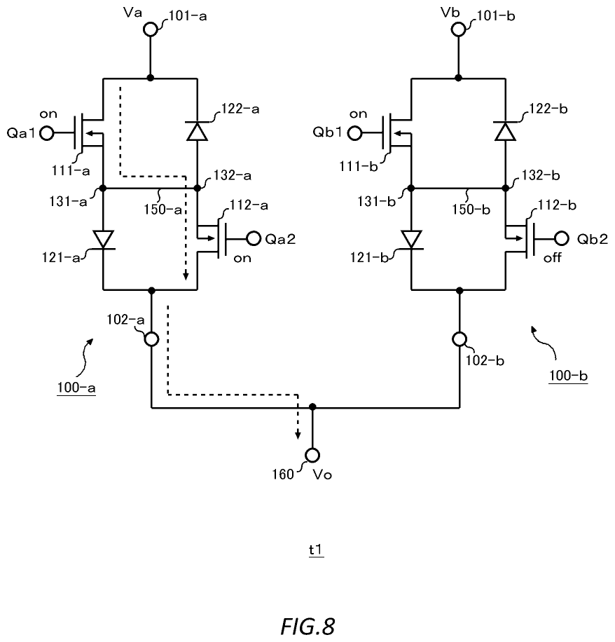

FIG. 8 illustrates a state at time t1 of FIG. 6. Time t1 is one example of a first timing. At time t1, the gate voltage Qb1 transitions from L level to H level. In this case, the first silicon carbide transistor 111-b transitions to an on state. However, a voltage Vo of the terminal 160 is approximately equal to the voltage Va of the first terminal 101-a. Therefore, the voltage Vb of the first terminal 101-b is lower than the voltage Vo of the terminal 160. Accordingly, even if the first silicon carbide transistor 111-b transitions to the on state, no current flows from the first terminal 101-b to the second terminal 102-b.

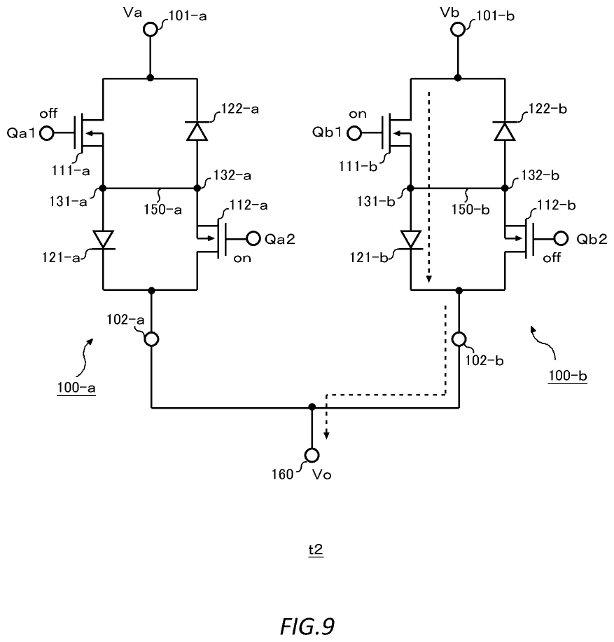

FIG. 9 illustrates a state at time t2 of FIG. 6. Time t2 is one example of a second timing. At time t2, the gate voltage Qa1 transitions from H level to L level. In this case, the first silicon carbide transistor 111-a transitions to an off state. Thereby, current from the first terminal 101-a to the second terminal 102-a can be cut off. Note that, in the states shown in FIGS. 7 and 8, by lowering current that flows in a first diode 121-a, reverse recovery losses in the first diode 121-a can be reduced. By keeping the second silicon carbide transistor 112-a in an on state at time t2, a path for current to flow reversely from the terminal 160 to the first terminal 101-a can remain.

If the first silicon carbide transistor 111-a transitions to an off state, the voltage Vo of the terminal 160 is disconnected from the voltage Va of the first terminal 101-a. Therefore, a forward voltage is applied to the first silicon carbide transistor 111-b and a first diode 121-b, and current flows in the second bidirectional switch 100-b. That is, by controlling the first silicon carbide transistor 111-a, cutting off current in the first bidirectional switch 100-a, and conducting current in the second bidirectional switch 100-b can be synchronously conducted.

As described above, by lowering a start-up voltage of the first diode 121-b to be less than a start-up voltage of a built-in diode of the second silicon carbide transistor 112-b, current can be prevented from flowing into the second silicon carbide transistor 112-b in the state shown in FIG. 9. Therefore, expansion of a stacking fault in the second silicon carbide transistor 112-b can be prevented.

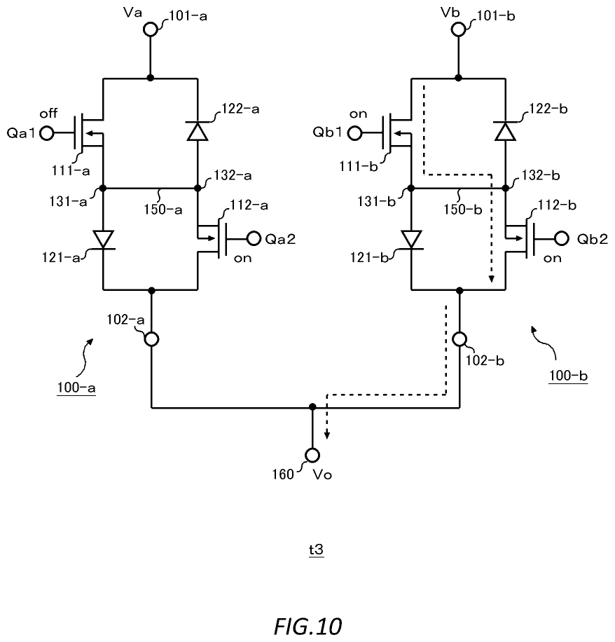

FIG. 10 illustrates a state at time t3 of FIG. 6. Time t3 is one example of a third timing. At time t3, the gate voltage Qb2 transitions from L level to H level. In this case, the second silicon carbide transistor 112-b transitions to an on state. Thereby, a large amount or the entire amount of current from the first silicon carbide transistor 111-b can flow into the second silicon carbide transistor 112-b. That is, current can be prevented from flowing into a second diode 122-b. In this way, when the second bidirectional switch 100-b transitions to an off state, reverse recovery losses in the second diode 122-b can be reduced.

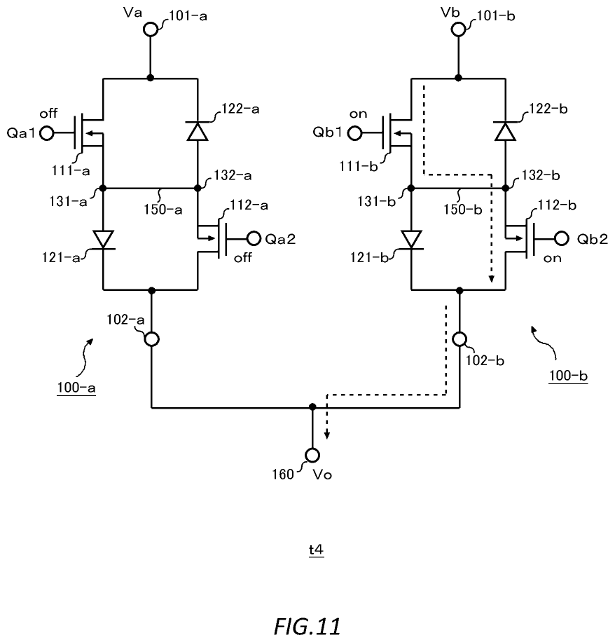

FIG. 11 illustrates a state at time t4 of FIG. 6. Time t4 is one example of a fourth timing. At time t4, the gate voltage Qa2 transitions from H level to L level. In this case, the second silicon carbide transistor 112-a transitions to an off state. Thereby, a current path from the second terminal 102-a toward the first terminal 101-a is cut off, so that the first bidirectional switch 100-a can be turned off. As long as it is in a state in which no current flows from the second terminal 102-a into the first terminal 101-a, the processing at time t4 may be conducted simultaneously with the processing at time t3, or even earlier than time t3. This state can be judged by monitoring a voltage of each terminal. For example, if the voltage Va is higher than both of the voltages Vb and Vo, the processing at time t4 may be conducted simultaneously with the processing at time t3, or even earlier than time t3.

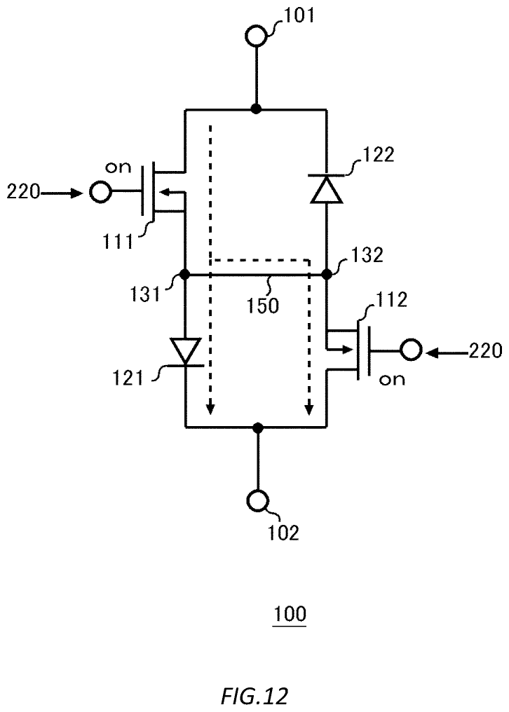

FIG. 12 is a diagram showing another example of operations of the bidirectional switch 100 in an on state. A device temperature of the bidirectional switch 100 in the present example is higher than that of the bidirectional switch 100 shown in FIG. 4. If the device temperature is high, a forward voltage of the first diode 121 may be low, so that current that flows in the first diode 121 may increase. Therefore, reverse recovery losses may increase. Meanwhile, if the device temperature is high, on resistance of the second silicon carbide transistor 112 increases. If current that flows in the second silicon carbide transistor 112 is lowered, on-state losses are reduced. Therefore, losses can be reduced as a whole.

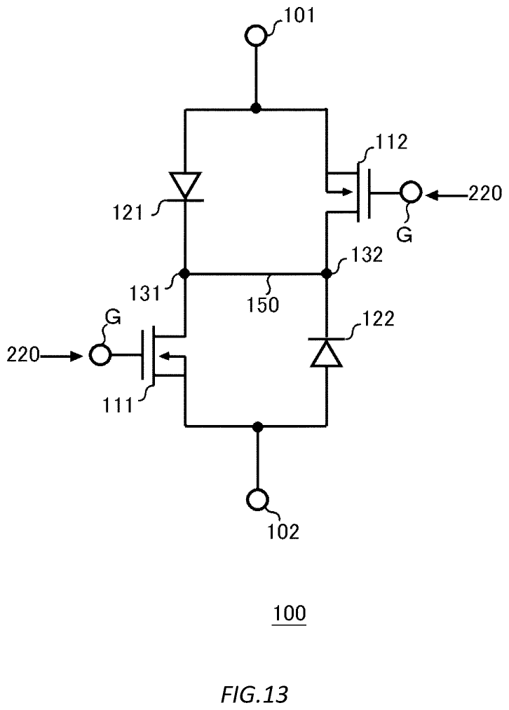

FIG. 13 is a diagram showing another example of architecture of the bidirectional switch 100. In the bidirectional switch 100 of the present example, compared to the architecture shown in FIG. 2, positions of the first diode 121 and the first silicon carbide transistor 111 are switched, and positions of the second diode 122 and the second silicon carbide transistor 112 are switched also. Otherwise, structure of the bidirectional switch 100 of the present example is the same as that shown in the example of FIG. 2.

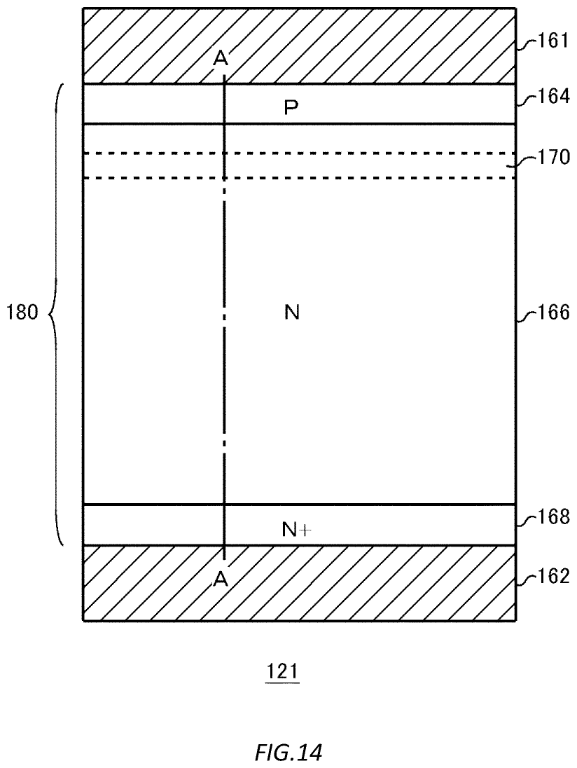

FIG. 14 is a diagram showing one example of structure of the first diode 121. Even though FIG. 14 shows the first diode 121, the second diode 122 also has the same structure. As described above, it is preferable that on voltage (i.e., forward voltage) of the first diode 121 is small. On the other hand, for a diode device, a local crystal defect may be formed by implanting charged particles such as helium into a semiconductor substrate in order to adjust carrier lifetime of holes. In this way, time in which tail current flows during reverse recovery is shortened, and thus reverse recovery losses are reduced. However, by shortening the carrier lifetime of the holes, on voltage is raised. The first diode 121 of the present example does not have a local crystal defect for adjusting carrier lifetime. Thereby, the on voltage of the first diode 121 is lowered.

The first diode 121 is a silicon diode having a P-N junction. The first diode 121 of the present example has a silicon semiconductor substrate 180, an anode electrode 161, and a cathode electrode 162. The semiconductor substrate 180 has an N type drift region 166, a P type anode region 164, and a N+ type cathode region 168. The anode region 164 is connected to the anode electrode 161, and the cathode region 168 is connected to the cathode electrode 162. The drift region 166 is arranged between the anode region 164 and the cathode region 168. A boundary between the drift region 166 and the anode region 164 is the P-N junction.

The diode device may have a lifetime adjustment region 170 in the drift region 166 or the like near the anode region 164. The lifetime adjustment region 170 is a region in which a crystal defect is locally formed by irradiating helium etc. By forming the crystal defect to which holes are attached, lifetime of the holes are shortened. The first diode 121 of the present example does not have the lifetime adjustment region 170 in the drift region 166. For example, the first diode 121 does not have a concentration peak of helium.

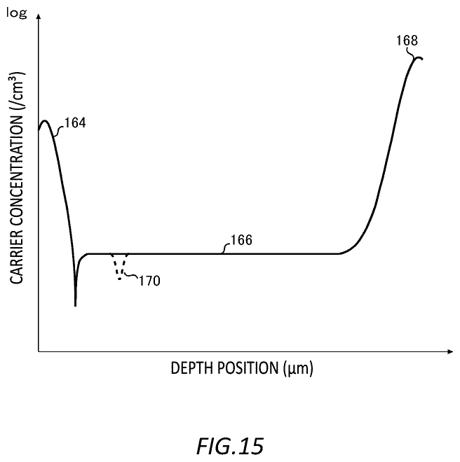

FIG. 15 illustrates one example of carrier concentration distribution taken along a line A-A of FIG. 14. The carrier concentration distribution may be measured by spreading resistance profiling (SRP) method, for example. If there is the lifetime adjustment region 170 provided, carrier concentration distribution in the drift region 166 has a local valley-shaped part (refer to the part shown by the dotted line in FIG. 15). On the other hand, in the first diode 121, as shown by the solid line in FIG. 15, the carrier concentration distribution in a depth direction of the drift region 166 has an approximately flat-shape. The phrase “approximately flat-shaped” refers to a fact that a variation range of the carrier concentration is equal to or less than ±20%, for example. Thereby, the on resistance of the first diode 121 can be lowered.

The first diode 121 of the present example does not have the lifetime adjustment region 170. Therefore, carrier lifetime of holes during turn-off is relatively long. When the first diode 121 is turned off, an average value of carrier lifetime of holes in the drift region 166 is may be equal to or more than 1 μs, 2 μs, or 3 μs. The same applies to carrier lifetime for the second diode 122. In addition, when the first diode 121 is turned off from a state in which the rated current described above is flowing through the first diode 121, a reverse recovery time period may be equal to or more than 1 μs, 2 μs, or 3 μs. The same applies to a reverse recovery time period for the second diode 122.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that embodiments added with such alterations or improvements can be included in the technical scope of the present invention.

What is claimed is:

1. A power conversion apparatus comprising multiple bidirectional switches, wherein
each of the multiple bidirectional switches has:
a first terminal and a second terminal;
a first silicon carbide transistor provided between the first terminal and the second terminal;
a first diode which is provided in series with the first silicon carbide transistor between the first terminal and the second terminal, of which a forward direction is a direction directed from the first terminal toward the second terminal, and of which on voltage is lower than on voltage of a built-in diode of the first silicon carbide transistor at a rated current of a corresponding bidirectional switch among the multiple bidirectional switches;
a second silicon carbide transistor provided in parallel with the first diode between the first terminal and the second terminal;
a second diode which is provided in series with the second silicon carbide transistor, and in parallel with the first silicon carbide transistor between the first terminal and the second terminal, of which a forward direction is a direction directed from the second terminal toward the first terminal, and of which on voltage is lower than on voltage of a built-in diode of the second silicon carbide transistor at the rated current of the corresponding bidirectional switch; and
a connection line which connects a first connection point between the first silicon carbide transistor and the first diode, and a second connection point between the second silicon carbide transistor and the second diode.

2. The power conversion apparatus according to claim 1, wherein
the first diode and the second diode are silicon diodes having P-N junctions.

3. The power conversion apparatus according to claim 1, wherein
a breakdown voltage of the first diode is higher than a breakdown voltage of the first silicon carbide transistor.

4. The power conversion apparatus according to claim 3, wherein
a breakdown voltage of the second diode is higher than a breakdown voltage of the second silicon carbide transistor.

5. The power conversion apparatus according to claim 1, wherein
a start-up voltage of the first diode is lower than a start-up voltage of the built-in diode of the second silicon carbide transistor.

6. The power conversion apparatus according to claim 5, wherein
a start-up voltage of the second diode is lower than a start-up voltage of the built-in diode of the first silicon carbide transistor.

7. The power conversion apparatus according to claim 1, further comprising
a control unit which controls, when turning on the corresponding bidirectional switch, both of the first silicon carbide transistor and the second silicon carbide transistor to be turned on.

8. The power conversion apparatus according to claim 7, wherein
when the corresponding bidirectional switch is turned on, current that flows in the first diode is smaller than current that flows in the second silicon carbide transistor.

9. The power conversion apparatus according to claim 8, wherein
when the corresponding bidirectional switch is turned on, the current that flows in the first diode is equal to or less than 10% of the current that flows in the second silicon carbide transistor.

10. The power conversion apparatus according to claim 7, wherein:
the multiple bidirectional switches include a first bidirectional switch and a second bidirectional switch; and
the control unit causes, when commutating current from the first bidirectional switch to the second bidirectional switch, the first silicon carbide transistor of the second bidirectional switch to transition to an on state at a first timing.

11. The power conversion apparatus according to claim 10, wherein
the control unit causes the first silicon carbide transistor of the first bidirectional switch to transition to an off state at a second timing that comes after the first timing.

12. The power conversion apparatus according to claim 11, wherein
the control unit causes the second silicon carbide transistor of the second bidirectional switch to transition to an on state at a third timing that comes after the second timing.

13. The power conversion apparatus according to claim 12, wherein
the control unit causes the second silicon carbide transistor of the first bidirectional switch to transition to an off state at a fourth timing that comes after the third timing.

14. The power conversion apparatus according to claim 1, wherein
in the first diode and the second diode, carrier lifetime of holes is equal to or more than 1 μs when the first diode and the second diode are turned off.

15. The power conversion apparatus according to claim 12, wherein
the control unit simultaneously causes the second silicon carbide transistor of the first bidirectional switch to transition to an off state at the third timing.

16. The power conversion apparatus according to claim 12, wherein
the control unit causes the second silicon carbide transistor of the first bidirectional switch to transition to an off state at a fourth timing that comes before the third timing.

17. A bidirectional switch, comprising:
a first terminal and a second terminal;
a first silicon carbide transistor provided between the first terminal and the second terminal;
a first diode which is provided in series with the first silicon carbide transistor between the first terminal and the second terminal, of which a forward direction is a direction directed from the first terminal toward the second terminal, and of which on voltage is lower than on voltage of a built-in diode of the first silicon carbide transistor at a rated current of the bidirectional switch;
a second silicon carbide transistor provided in parallel with the first diode between the first terminal and the second terminal;
a second diode which is provided in series with the second silicon carbide transistor, and in parallel with the first silicon carbide transistor between the first terminal and the second terminal, of which a forward direction is a direction directed from the second terminal toward the first terminal, and of which on voltage is lower than on voltage of a built-in diode of the second silicon carbide transistor at the rated current of the bidirectional switch; and
a connection line which connects a first connection point between the first silicon carbide transistor and the first diode, and a second connection point between the second silicon carbide transistor and the second diode.

18. The power conversion apparatus according to claim 2, wherein
a breakdown voltage of the first diode is higher than a breakdown voltage of the first silicon carbide transistor.

19. The power conversion apparatus according to claim 2, wherein
a start-up voltage of the first diode is lower than a start-up voltage of the built-in diode of the second silicon carbide transistor.

20. The power conversion apparatus according to claim 3, wherein
a start-up voltage of the first diode is lower than a start-up voltage of the built-in diode of the second silicon carbide transistor.
